(19) United States
(12) Patent Application Publication
(10) Pub. No.: US 2021/0011054 A1
(43) Pub. Date: Jan. 14, 2021

(54) SECURE HOLDER FOR PROBE AND TEST JIG USING THE SAME

(71) Applicant: TRIPLE WIN TECHNOLOGY(SHENZHEN) CO.LTD., Shenzhen (CN)

(72) Inventor: RUO-CHUN SU, Shenzhen (CN)

(21) Appl. No.: 16/549,154

(22) Filed: Aug. 23, 2019

(30) Foreign Application Priority Data
Jul. 10, 2019 (CN) 201910621694.3

(51) Int. Cl. G01R 3/00; G01R 1/04; G01R 1/067

(52) U.S. Cl. CPC G01R 3/00; G01R 1/067; G01R 1/0408

(57) ABSTRACT

A probe holder for securely holding a probe within a certain location includes a base and a limiting block. The base defines a first receiving cavity having a bottom. The bottom of the first receiving cavity defines at least one first through hole penetrating the base. The first through hole is stepped for abutting the probe in one direction. The limiting block is disposed on the base opposite to the first receiving cavity. The limiting block defines at least one second through hole corresponding to the first through hole, the second through hole is also stepped and serves as a second abutting portion against the probe moving in an opposite direction. A test jig using the probe holder is also provided.

### FIELD

The subject matter herein generally relates to test jigs.

### BACKGROUND

In the manufacturing process of camera modules, it is necessary to use test jigs to perform tests on the products. The probe is in a probe holder of a jig, the adapter plate and the module connector are applied during the test. Currently, a through hole is defined in the probe holder and under the probe, and the probe can easily fall out of the probe holder. The probe is very small device, it is difficult to retrieve after falling out and difficult to reinstall after being dropped, which affects the testing efficiency of the products. To prevent the probe from falling out of the probe holder, a traditional way is to fix the probe on the probe holder by adhesive tape, and then remove the tape after the adapter plate is installed. But the probe can still fall from the probe holder.

Therefore, there is room for improvement.

### BRIEF DESCRIPTION OF THE DRAWINGS

Implementations of the present technology will now be described, by way of embodiments, with reference to the attached figures.

FIG. 1 is a perspective view of a probe holder according to an embodiment of the present disclosure.

FIG. 2 is a perspective view of the probe holder of FIG. 1.

FIG. 3 is an exploded view of the probe holder of FIG. 1.

FIG. 4 is an exploded view of the probe holder of FIG. 1 from another angle.

FIG. 5 is a cross-sectional view along line V-V of FIG. 1.

FIG. 6 is an isometric view of the probe holder of FIG. 1 disposed on a fixed plate.

FIG. 7 is an isometric view of the fixing plate of FIG. 6 on an adapter plate.

FIG. 8 shows a limiting block of the probe holder in another embodiment.

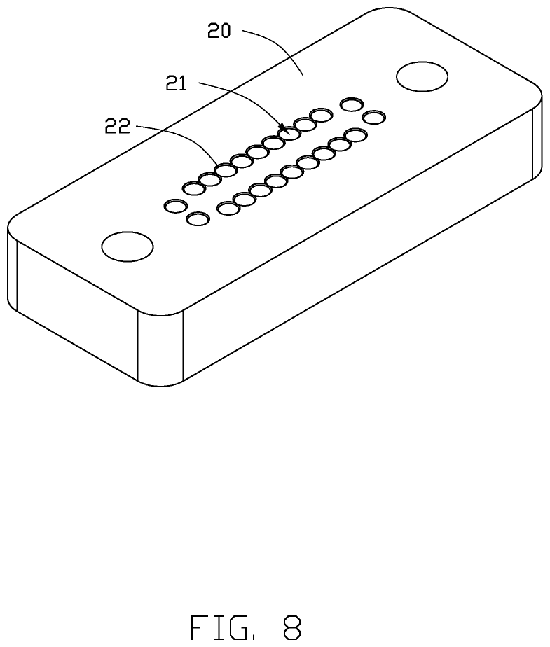

### DETAILED DESCRIPTION

The present disclosure is made in conjunction with the accompanying drawings. Specific embodiments of the present disclosure are described.

In the following description, when an element is described as being “fixed to” another element, the element can be fixed to the another element with or without intermediate elements. When an element is described as “connecting” another element, the element can be connected to the other element with or without intermediate elements.

Without a given definition otherwise, all terms used have the same meaning as commonly understood by those skilled in the art. The term “and/or” means including any and all combinations of one or more of associated listed items. The terms “top”, “bottom”, “upper”, “lower”, “left”, “right”, “front”, “back”, and the like, as used herein, are for illustrative purposes only.

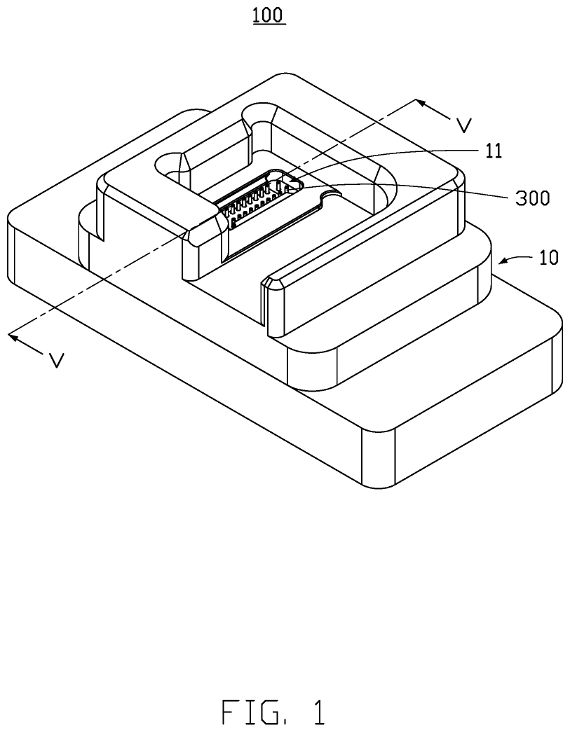

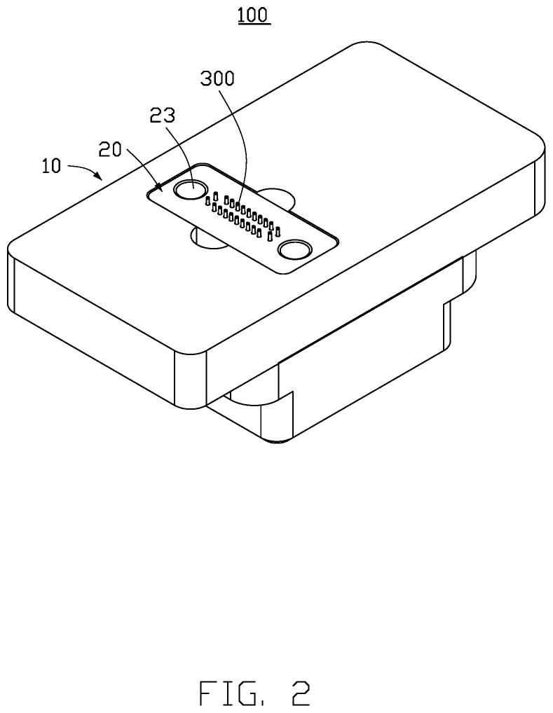

Referring to FIGS. 1 and 2, in an embodiment, a test jig (not labeled) is provided for testing products. A plurality of probes 300 are provided in the test jig to electrically connect several structures in the test jig. A probe holder 100 is provided to hold the probes 300 in place. In the embodiment, the products for testing are camera modules.

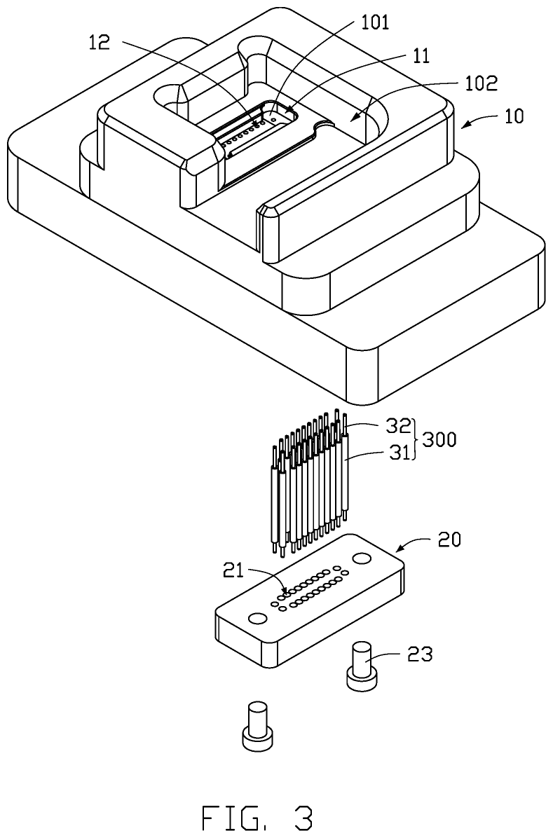

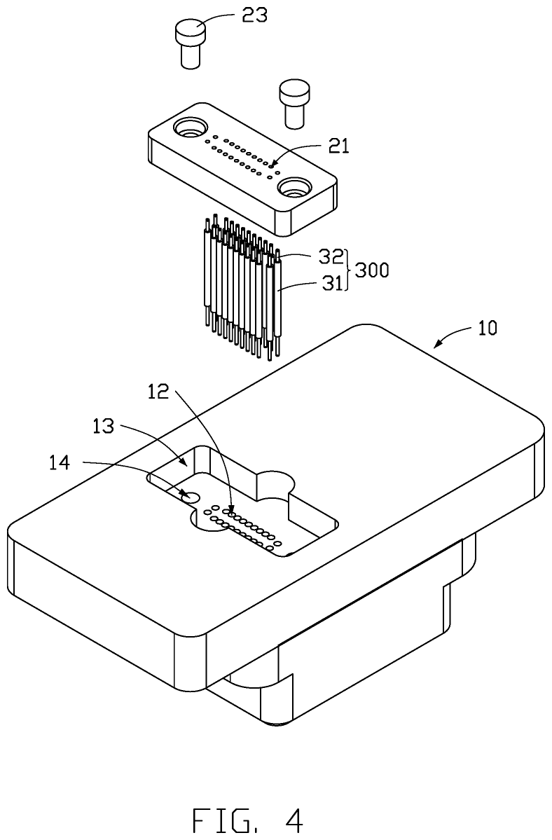

Referring to FIGS. 3 and 4, the probe holder 100 includes a base 10. The base 10 defines a first receiving cavity 11. A bottom 101 of the first receiving cavity 11 defines a plurality of first through holes 12 penetrating the base 10. The probes 300 are disposed in the first through holes 12 with one probe 300 corresponding to one first through hole 12 and protruding from the first through hole 12 at both ends. The probe holder 100 further includes a limiting block 20. The limiting block 20 is disposed on the base 10 opposite to the first receiving cavity 11. The limiting block 20 defines a plurality of second through holes 21 corresponding to the first through holes 12. An end of each of the probes 300 protrudes into one of the second through holes 21 and abuts against the limiting block 20, and the other end of the probe 300 abuts against the base 10.

Referring to FIGS. 3-5, the base 10 is substantially a rectangular block defining a receiving space 102. The receiving space 102 is configured for receiving a camera module to be tested. The first receiving cavity 11 is defined at a bottom of the receiving space 102. In an embodiment, the first through holes 12 are arranged and distributed in a rectangular pattern. Each of the first through holes 12 is a stepped hole and includes a first cylindrical hole portion 121 far away from the first receiving cavity 11 and a second cylindrical hole portion 122 connected to an end of the first cylindrical hole portion 121. A diameter of the second cylindrical hole 122 is smaller than a diameter of the first cylindrical hole 121, thus a first step 123 is formed therebetween. The first step 123 serves as a first abutting portion 123 for abutting the probe 300, When a probe 300 is disposed in a first through hole 12, an end of the probe 300 protrudes out to the first receiving cavity 11 to electrically connect to the product to be tested.

The base 10 defines a second receiving cavity 13 for receiving the limiting block 20. In the embodiment, the second receiving cavity 13 is opposite to the first receiving cavity 11. It can be understood that the shape of the base 10 is not limited to being a rectangular block, specifically, the shape of the base 10 can be changed to suit the products to be tested. The number and arrangement of the first through holes 12 can also be changed to suit the products. For example, the first through holes 12 can be arranged in three parallel columns.

Referring to FIGS. 3-5, the limiting block 20 has a substantially rectangular parallelepiped shape. The second through holes 21 are arranged and distributed to correspond to the first through holes 12. Each of the second through holes 21 includes a third cylindrical hole portion 211 adjacent to the first cylindrical hole portion 121 and a fourth cylindrical hole portion 212 away from the first cylindrical hole portion 121. A diameter of the fourth cylindrical hole portion 212 is smaller than a diameter of the third cylindrical hole portion 211, thus forming a second step 213 therebetween. The second step 213 serves as a second abutting portion 213 for abutting the probe 300. The other end of the probe 300 protrudes out of the limiting block 20 through the fourth cylindrical hole portion 212 and electrically connects with others.

Referring to FIG. 3, the probe 300 includes a first probe body 31 and two second probe bodies 32, the bodies 32 are at opposite ends of the first probe body 31. A diameter of the first probe body 31 is larger than a diameter of each second probe body 32. The diameter of the first probe body 31 is substantially the same as or slightly smaller than the diameter of the first cylindrical hole portion 121 and the third cylindrical hole portion 211, thereby clearance for fitting can be created between the first probe body 31 and the first cylindrical hole portion 121 and the third cylindrical hole portion 211. The first probe body 31 can be easily inserted in the first cylindrical hole portion 121 and the third cylindrical hole portion 211. The diameter of the second probe body 32 is substantially the same as or slightly smaller than the diameter of the second cylindrical hole portion 122 and the fourth cylindrical hole portion 212, thereby clearance for fitting can be created between the second probe body 32 and the second cylindrical hole portion 122 and the fourth cylindrical hole portion 212. The second probe body 32 can be easily inserted in the second cylindrical hole portion 122 and the fourth cylindrical hole portion 212. In alternative embodiment, the probe 300 has different structure. For example, the second probe bodies 32 can be of different diameters from each other. The diameters of the first through hole 12 and of the second through hole 21 may also be different.

A fixing recess 14 and a locking member 23 are provided for fixing the limiting block 20 on the base 10. Specifically, in the embodiment, the fixing recess 14 is defined on the base 10, and the locking member 23 is formed on the limiting block 20. The locking member 23 is engaged in the fixing recess 14 to fix the limiting block 20 on the base 10. In an embodiment, the locking member 23 can be a locking screw, and the fixing recess 14 can be a threaded hole defined on both the base 10 and the locking member 23. There are two locking members 23 and two fixing recesses 14 to fix the limiting block 20 on the base 10. The number of the locking members 23 and the fixing recesses 14 are changeable according to actual needs.

In another embodiment, the locking member 23 can be a resilient piece and the fixing recess 14 can be a slot. There would be two resilient pieces and two slots to fix the limiting block 20 on the base 10. The resilient pieces can be disposed at opposite ends of the limiting block 20, and the slots can be defined on the base 10 to correspond to locations of the resilient pieces. When mounting the limiting block 20 on the base 10, the resilient pieces are biased and deformed toward each other, and then the limiting block 20 is moved so that the resilient pieces are moved to the slots of the base 10. The resilient pieces are released and inserted in the slots, thereby the resilient pieces are fastened in the slots, and thereby fixing the limiting block 20 on the base 10. It can be understood that in alternative embodiments, the limiting block 20 and the base 10 can be fixed by other manner.

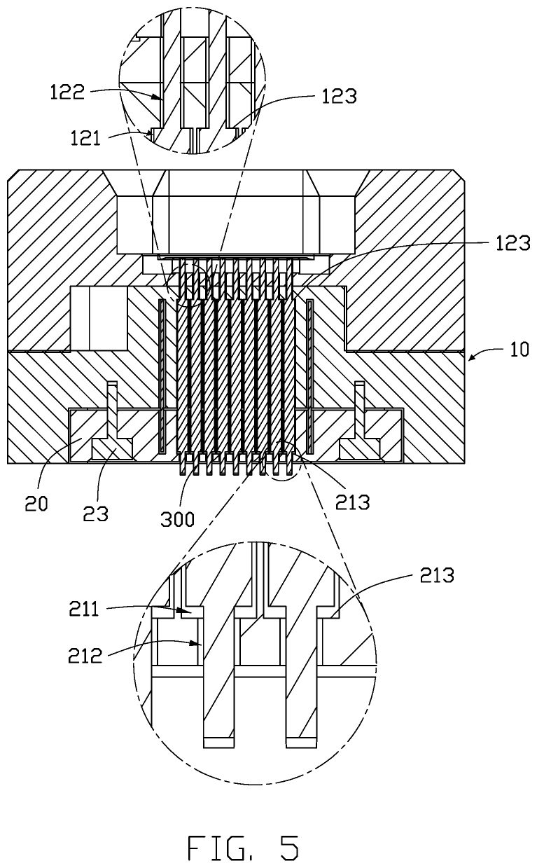

Referring to FIG. 5, when the probe 300 is inserted in the base 10 from one end of the second receiving cavity 13, one of the second probe bodies 32 is partially disposed in the second cylindrical hole portion 122 and partially exposed in the first receiving cavity 11. The first probe body 31 is partially disposed in the third cylindrical hole portion 121 and partially exposed in the second receiving cavity 13. One end of the first probe body 31 is abutted against the first holding portion 123, When the limiting block 20 is fixed on the base 10, the first probe body 31 is partially received in the third cylindrical hole portion 211, and the other end of the first probe body 31 is abutted on the second abutting portion 213. The other of the second probe bodies 32 is partially disposed in the fourth cylindrical hole portion 212, and partially disposed outside of the fourth cylindrical hole portion 212. Thus, the probe 300 is precisely fixed in the probe holder 100.

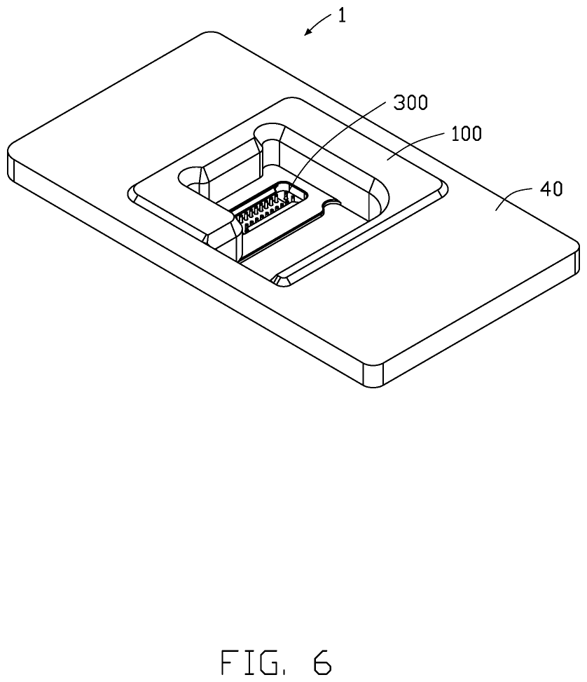

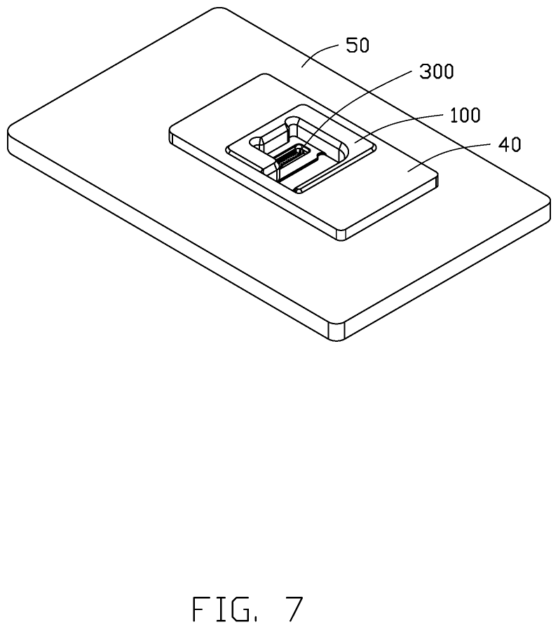

Referring to FIGS. 6 and 7, the test jig 1 includes a fixing plate 40, and the fixing plate 40 is provided with a third through hole (not shown), and the probe holder 100 is disposed in the third through hole. The test jig further includes an adapter plate 50. When the adapter plate 50 is disposed on the fixing plate 40, the probe 300 protrudes out of the limiting block 20 and electrically connects with the adapter plate 50. When the product to be tested is placed in the receiving space 102 of the base 10 the probe 300 electrically connects the tested product to the adapter plate 50.

Referring to 8, in an embodiment, the limiting block 20 is provided with a guiding slope 22 for guiding the probe 300 into a second through hole 21. Specifically, in the embodiment, the guiding slope 22 is formed on an end of the second through hole 21 facing the bottom of the second receiving cavity 13. If a probe 300 does not accurately enter a second through hole 21, the probe 300 can be guided by the guiding slope 22 to enter the second through hole 21 when moving the limiting block 20 relative to the base 10.

The embodiments of the present disclosure provide a probe holder 100 and a test jig using the probe holder 100. The base of the probe holder defines at least one first through hole 12, and the limiting block 20 defines at least one second through hole 21 corresponding to the first through hole 12. The first abutting portion 123 in the first through hole 12 limits the probe 300 toward a direction and the second abutting portion 213 in the second through hole 21 limits the probe 300 toward an opposite direction. Thereby the probe 300 is fixed in the probe holder 100. The probe holder 100 has a simple structure and is convenient to use. The limiting block 20 is directly disposed on the base 10. Disassembly of the limiting block from the base 10 is not required when installing the adapter plate 50, thereby the probe 300 cannot fall out of the base 10. The probe holder 100 is also easy to be disassembled to replace the probes 300.

The embodiments shown and described above are only examples. Even though numerous characteristics and advantages of the present technology have been set forth in the foregoing description, together with details of the structure and function of the present disclosure, the disclosure is illustrative only, and changes can be made in the detail, including in matters of shape, size, and arrangement of the parts within the principles of the present disclosure, up to and including the full extent established by the broad general meaning of the terms used in the claims.

What is claimed is:

1. A probe holder for fixing a probe, comprising a base and a limiting block, wherein the base defines a first receiving cavity having a bottom, the bottom of the first receiving cavity defines at least one first through hole penetrating the base, the first through hole is stepped and comprises a first step, the first step serves as a first abutting portion for abutting the probe and limiting the probe toward a direction, the limiting block is disposed on the base opposite to the first receiving cavity, the limiting block defines at least one second through hole corresponding to the first through hole, the second through hole is stepped and comprises a second step, the second step serves as a second abutting portion for abutting the probe and limiting the probe toward an opposite direction.

2. The probe holder according to claim 1, wherein the first through hole comprises a first cylindrical hole portion away from the first receiving cavity and a second cylindrical hole portion adjacent to the first receiving cavity, the second cylindrical hole portion has a diameter smaller than a diameter of the first cylindrical hole portion.

3. The probe holder according to claim 1, wherein the second through hole comprises a third cylindrical hole portion adjacent to the first cylindrical hole portion and a fourth cylindrical hole portion away from the first cylindrical hole portion, the fourth cylindrical hole portion has a diameter smaller than a diameter of the third cylindrical hole portion.

4. The probe holder according to claim 3, wherein the limiting block is provided with a guiding slope for guiding the probe into the second through hole.

5. The probe holder according to claim 1, wherein the base defines a second receiving cavity for receiving the limiting block.

6. The probe holder according to claim 5, further comprising at least one fixing recess and at least one locking member for fixing the limiting block on the base.

7. The probe holder according to claim 6, wherein the fixing recess is a threaded hole defined on both the base and the limiting block, and the locking screw is a locking screw screwed in the threaded hole.

8. The probe holder according to claim 6, wherein the fixing recess is a slot and the locking member is a resilient piece, the resilient piece is fastened in the slot.

9. A test jig comprising a fixing plate and a probe holder disposed on the fixing plate for fixing a probe, wherein the probe holder comprises a base and a limiting block, the base defines a first receiving cavity having a bottom, the bottom of the first receiving cavity defines at least one first through hole penetrating the base, the first through hole is stepped and comprises a first step, the first step serves as a first abutting portion for abutting the probe and limiting the probe toward a direction, the limiting block is disposed on the base opposite to the first receiving cavity, the limiting block defines at least one second through hole corresponding to the first through hole, the second through hole is stepped and comprises a second step, the second step serves as a second abutting portion for abutting the probe and limiting the probe toward an opposite direction.

10. The test jig according to claim 9, further comprising an adapter plate disposed on the fixing plate, the adapter plate electrically connecting with the probe when the probe is hold by the probe holder and protrudes out of the limiting block.

11. The test jig according to claim 9, wherein the first through hole comprises a first cylindrical hole portion away from the first receiving cavity and a second cylindrical hole portion adjacent to the first receiving cavity, the second cylindrical hole portion has a diameter smaller than a diameter of the first cylindrical hole portion.

12. The test jig according to claim 9, wherein the second through hole comprises a third cylindrical hole portion adjacent to the first cylindrical hole portion and a fourth cylindrical hole portion away from the first cylindrical hole portion, the fourth cylindrical hole portion has a diameter smaller than a diameter of the third cylindrical hole portion.

13. The test jig according to claim 12, wherein the limiting block is provided with a guiding slope for guiding the probe into the second through hole.

14. The test jig according to claim 9, wherein the base defines a second receiving cavity for receiving the limiting block.

15. The test jig according to claim 14, further comprising at least one fixing recess and at least one locking member for fixing the limiting block on the base.

16. The test jig according to claim 15, wherein the fixing recess is a threaded hole defined on both the base and the limiting block, and the locking screw is a locking screw screwed in the threaded hole.

17. The test jig according to claim 15, wherein the fixing recess is a slot and the locking member is a resilient piece, the resilient piece is fastened in the slot.
